(19) United States
(12) Patent Application Publication
(10) Pub. No.: US 2013/0094271 A1
(43) Pub. Date: Apr. 18, 2013

(54) CONNECTION OF MULTIPLE SEMICONDUCTOR MEMORY DEVICES WITH CHIP ENABLE FUNCTION

(71) Applicant: Roland Schuetz, Ottawa (CA)

(72) Inventor: Roland Schuetz, Ottawa (CA)

(73) Assignee: MOSAID TECHNOLOGIES INCORPORATED, Ottawa (CA)

(21) Appl. No.: 13/588,195

(22) Filed: Aug. 17, 2012

Related U.S. Application Data
(60) Provisional application No. 61/525,950, filed on Aug. 22, 2011.

(51) Int. Cl. G11C 5/06

(52) U.S. Cl. CPC G11C 5/06
USPC 365/63

(57) ABSTRACT

A system comprising a plurality of memory devices coupled by a common bus to a controller has a single serially coupled enable signal per channel. Each memory device or chip comprises a serial enable input and enable output and a register for storing a device identifier, e.g., chip ID. The memory devices are serially coupled by a serial enable link, for assertion of a single enable signal to all devices. This parallel data and serial enable configuration provides reduced per-channel pin count, relative to conventional systems that require a unique enable signal for each device. In operation, commands on the common bus targeting an individual device are asserted by adding an address field comprising a device identifier to each command string, preferably in an initial identification cycle of the command. Methods are also disclosed for initializing the system, comprising assigning device identifiers and obtaining a device count, prior to normal operation.

### CROSS REFERENCE TO RELATED APPLICATIONS

This application claims priority from U.S. Provisional Patent Application Ser. No. 61/525,950, entitled “Method and Apparatus for Reducing Pin Count on Semiconductor Chips”, filed 22 August 2011, which is incorporated herein by reference in its entirety.

### TECHNICAL FIELD

The present invention relates to semiconductor devices, and more particularly to systems, apparatus and methods for connection of a plurality of memory devices with a function of chip enable or device selection.

### BACKGROUND

Memory systems comprising one or more memory devices are widely used in digital equipment including consumer devices, such as computers, portable audio/video systems, cameras, solid state drives (SSDs) and the like. Memory devices include non-volatile memories, such as, for example, flash memories and volatile memories, such as, for example, dynamic random access memories (DRAMs). For example, non-volatile memories such as flash memories or high speed volatile DRAMs are used for the memory devices, depending on the application or task required. Flash memories are implemented, for example, as NOR flash or NAND flash memories. NAND flash memory provides for a higher memory density per area due to its more compact memory array structure.

SSDs comprising flash memory devices, such as, for example, NAND flash memories, provide high density memories that are non-volatile and compact relative to conventional hard disk drives. Large capacity memory systems may be provided by interconnecting multiple flash memory devices, typically using a common bus, i.e., a parallel data bus architecture. Such systems comprise a memory controller and a parallel multidrop bus with 8, 10 or more flash memory devices per bus, for example. Systems comprising a memory controller and serially interconnected memory devices arranged in a ring or loop for serial data transfer are also known. The memory controller provides logic for interfacing a memory device to a host system, comprising a processor, for data storage and retrieval.

When multiple memory devices are interconnected, the controller manages flow between individual memory devices and external interfaces for storing data, accessing data and manipulating data in the system. A command structure is used by the controller to provide requests to individual memory devices storing data. The command structure may be dependent on the configuration of the interconnected memory devices and can impact performance of the system.

For parallel interconnection, each memory device has multiple input/output (I/O) pins to accommodate the parallel transfer of data and address information as well as control signals to each of the devices. When multiple individual devices are in communication with the controller via a common bus, then only one of the individual devices is asserted at any given time. Thus each memory device receives a unique chip enable signal (hereinafter called to as “CEb signal”) from the controller to allow individual memory devices to be enabled or disabled as required. The CEb signal is used to associate a given bus transaction with a particular memory device. That is, on asserting a new command, a CEb signal to a target device enables the individual memory device to participate in the transaction, while other memory devices remain inactive. Thus, in addition to multiple I/O pins for parallel data transfer, each device requires individual control pins for CEb signals and other control signals. Thus, it is generally recognized that a problem arises with SSDs and SSD controllers designed with a parallel data bus and a large number of flash memory channels due to the large number of I/O pins required per channel. High pin counts increase printed circuit board (PCB) complexity and drive up the cost of the controllers. Large numbers of long interconnections are also contribute to undesirable effects such as crosstalk or propagation delays that impact performance and signal integrity, particularly for high speed applications.

On the other hand, for serial data transfer, commands from the controller are passed from device to device through a serial link, thus requiring fewer pins per channel. Advantageously, a serial of arrangement can provide for higher data throughput and enable higher speed operation. However, each memory device requires an address, e.g., a device ID, and for example, the first byte of any serial command must be a device ID byte which is used to address a target device. Instead of receiving a unique CEb signal, a device participates in a transaction when a serial command is received with a matching device ID; otherwise the command is forwarded to the next serially linked device. Since all devices must remain active to forward commands from one device to another using a serial data link, other issues may arise, such as higher power consumption (relative to a parallel bus architecture where devices are enabled or disable individually by a unique CEb signal (see for example, US Patent Publication No. US2008/0201588 entitled “Semiconductor Device and Method for Reducing Power Consumption in a System having Interconnected Devices”)

The present application is directed to parallel bus architectures and addresses issues with respect to high per-channel pin count overhead for memory controllers for parallel bus memory systems, particularly with respect to the requirement for control signals that are unique to each memory device, such chip enable signals (CEb signals) for each device. It is desirable to reduce the ratio of control pins to data pins.

For example, for a conventional parallel bus flash memory system, the memory controller must provide multiple control and data signals to each memory device on the multidrop bus. Signals that are common to all devices on the bus include, for example, Command Latch enable (CLE), Address Latch Enable (ALE), Data Input/Output IO[x:0], Write Enable (WEb), Read Enable (REb), Data Strobe (DQS) and Write Protect (WPb) signals. Signals unique to each device on the bus include, for example, Chip Enable (CEb) and Ready/Busy (RBb) signals. I/O pins are used to receive a command and an address, i.e., to receive data at a write operation and to output data at a read operation.

Each flash memory device on a parallel bus is given a unique device or chip-enable signal, CEb, that is used to associate a given bus transaction with a particular device or chip, e.g., a flash memory device. In other words, because CEb is used to address a particular memory device, each memory device in the memory system needs a unique CEb signal connected between it and the controller, for example, as illustrated in FIG. 2. Thus, it is apparent that for systems comprising a large number of flash memory devices, the controller requires a corresponding number of CEb and RBb input/output pins for each flash memory channel.

The CEb signal functions as follows. When the controller wishes to transact with a given flash chip on the bus, it first asserts the CEb connected to the target flash device and then issues the command and carries out any other parts of the transaction. Only one CEb is asserted at a time, guaranteeing that only the chip connected to the asserted CEb will participate in a given transaction. Thus the CEb signal allows for individual memory devices to be activated while other devices are passive. On the other hand, in SSDs that have many channels and many flash chips per channel, the memory controller requires a large number of CEb pins. This drives up the cost of the controller chip and PCB. Similarly RBb signals, which prevent the controller from accessing a selected memory which is conducting a read or write operation, are also required for each individual memory device.

Thus it is desirable to provide devices, systems and methods that reduce the per-channel pin-count in parallel bus arrangements, particularly for high capacity memory systems, such as, for example, flash memory systems for SSDs, comprising multiple memory devices per channel.

### SUMMARY

In accordance with one aspect of the present invention, there is provided a connection of a plurality of semiconductor memory devices with chip enable function.

Aspects of the present invention provide systems, devices and methods for addressing a plurality of individual memory devices on a common bus, i.e., a parallel interface, such as a multidrop bus, using a single serial enable signal, by assigning a device identifier to each memory device. The device identifier is, for example, a device identification (ID) or chip ID, such as a word, device address, or cycle. To allow commands to be targeted to a specific memory device, the device identifier of the targeted device is added to an address field of each command asserted on the common bus.

One aspect of the present invention provides a system comprising a controller and a plurality of (N) memory devices, N being an integer greater than one. The plurality of memory devices is interconnected to the controller on a common bus comprising parallel links. The plurality of memory devices is also interconnected in series by a serial chip enable link from a single enable output of the controller. The system may comprise a parallel data and serial enable configuration.

For a system comprising first and second memory devices, each of the first and second memory devices may comprise a serial enable input and a serial enable output, the enable input of the first memory device being coupled to the enable output of the controller, and the enable output of the first memory device being coupled to a enable input of the second memory device in the series, for providing a single enable signal from the controller for enabling or disabling each of the plurality of memory devices.

For a system comprising a plurality of memory devices, each memory device may comprise a serial enable input and a serial enable output, and the serial enable link may connect each of the plurality of memory devices in series, a enable input of a first memory device coupled to the enable output of the controller, and each enable output of the first memory device and of other memory devices coupled respectively to a enable input of a subsequent memory device in the series, for providing a single serial enable signal from the controller for enabling or disabling each of the plurality of memory devices.

In one aspect, there is one enable signal output from the controller which is connected serially to all memory devices on the channel, for example N devices. That is successive enable outputs and enable inputs of memory devices are connected serially, so that the single enable signal is propagated serially from the first device (e.g., ID=0) to the second (e.g., ID=1) and then on to the m-th memory device of the channel. The chip enable output of the last, or N-th, device is left open or terminated.

Each of the plurality of memory devices is configured to store an assigned identifier. For addressing an individual memory device, the controller is configured to assert commands on the command bus comprising an identification cycle, each command comprising a command string having an address field containing the device identifier of the individual memory device.

Preferably, the identification cycle comprises a first cycle of a command string, although it is a second or subsequent cycle of the command.

By utilizing an additional address field in each command, i.e., comprising a device ID, the need for a controller having a unique chip-enable enable output signal is removed. Thus the controller requires only one enable output pin per channel rather than a separate enable output pin for each memory device in a channel, thereby reducing the per-channel pin-count.

Another aspect of the present invention provides a memory device comprising a plurality of parallel input/output connections (or parallel interface), a serial chip enable input and a serial chip enable output, and a storage element, e.g., a register, for storing a device identifier, e.g., a device ID or chip ID. The serial chip enable input and output allow for a plurality of memory devices to be serially interconnected, so that each can be addressed by an enable signal from a single enable output of the controller. The register allows to a device identifier to be assigned dynamically, and locally stored in each device. Control circuitry, e.g., comprising an ID comparator, e.g., logic elements for performing a matching function, of the memory device is configured to compare a received device identifier, i.e., a device ID extracted from an address field of the command string, with the stored device identifier. If there is a match, the memory device will participate in the transaction, or otherwise the memory device ignores the command and awaits another command.

Another aspect of the present invention provides a method of operating a system comprising a plurality of memory devices and a controller, wherein: the plurality of memory devices and the controller are interconnected through a common bus providing parallel links, each memory device comprises a serial enable input and a serial enable output, and the controller has a single enable output pin for providing a enable signal to the enable input of a first memory device, the plurality of memory devices being coupled in series through a serial enable link, the enable output of each memory device being serially coupled to the enable input of a subsequent memory device in the series.

Yet another aspect of the present invention provides a method of addressing individual memory devices for controlling data transfer in a system comprising a controller and a plurality of memory devices that are interconnected by a parallel link and wherein the plurality of memory devices are connected in series by a serial enable link from the controller, the method comprising: in an initialization phase, assigning to each of the memory devices a unique device identifier; and then, in normal operation: asserting a single enable signal via the serial enable link for enabling each of the plurality of memory devices; asserting a command on the parallel link, wherein an address field of an identification cycle of the command comprises a device identifier of an individual device of the plurality of memory device; at each memory device, in an identification cycle, extracting the device identifier, determining if the extracted device identifier matches the assigned device identifier; and in the memory device matching the extracted device identifier, further processing other cycles of the command.

Operation may comprise two phases: a first phase, or initialization, comprises assigning a device address, which may optionally include performing a device count, and then a second phase, or normal operation, using a command comprising the device ID of the device that is to participate in a transaction.

For example, the register for storing a device ID programmed shortly after start up, only. In embodiments, on initialization of the system, i.e., after power-up, each memory device on a channel is assigned a unique chip ID by the controller, which the controller later uses to address individual devices during normal operation. The step of assigning the device ID may be done as a first step, or cycle, immediately after power up, or later in an operation, as appropriate.

The assigning to each of the plurality of memory devices a unique device identifier may comprise: asserting an enable signal via the serial enable link, and as a transition of the enable signal propagates serially through each of the memory devices incurring a pre-defined delay in each memory device, asserting a command on the parallel link, during a time window corresponding to the pre-defined delay, for storage of a respective device identifier in the device identifier register of the corresponding memory device.

Another aspect of the present invention provides a memory system comprising: a plurality of memory devices, each of the memory devices comprising a storage element configured to store a device identifier; a parallel interface providing links via a common bus to each memory device; and a serial enable interface providing a serial enable link connecting each of the memory devices in series, for asserting a single enable signal for enabling or disabling the plurality of memory devices.

Another aspect of the present invention provides a memory controller for controlling a channel of a system comprising a plurality of memory devices, the controller comprising: an interface for a common bus configured to provide parallel links to each memory device, and a single serial enable output per channel.

The memory controller may comprise an identification producer configured to produce a unique identifier to be assigned to each of the plurality of memory devices, and a command provider configured to provide a command to the common bus during a command cycle comprising an identification cycle, the command string of the identification cycle having an address field comprising the device identifier of an individual memory device to participate in a transaction. The device identifier may be contained in an address field of an identification cycle of the command, such as a first cycle of a command string.

For assignment of device identifiers, the command provider may be configured to: assert a enable signal via the serial enable output, and as the transition of the enable signal propagates serially through each of the memory devices incurring a pre-defined delay in each memory device, assert a command cycle on the parallel link, during a time window corresponding to the pre-defined delay, for storage of a respective device identifier in a device identifier register of a corresponding memory device.

Another aspect of the present invention provides a command structure for addressing individual memory devices in a system comprising a controller and a plurality of memory devices, the plurality of memory devices being interconnected to a common bus to provide parallel links, and serially interconnected via a single serial enable link from the controller, the command structure comprising: a command string comprising an identification cycle comprising an address field containing a device identifier for an individual memory device. The identification cycle comprises a first cycle in the command string, or a second subsequent cycle in the command string.

For example, the system comprises a controller having identification circuitry configured to assign each device a unique device identifier or chip ID, e.g., a chip address, word or cycle. In an embodiment, the controller uses an input-to-output delay of the common enable signal as it passes from the enable input to the enable output through each device. Each device may comprise a delay element, e.g., a buffer providing a known delay. For example, the difference between the times when each chip receives the transition of enable is used to program each successive chip in the enable serial link with a unique chip ID.

Conveniently, the single enable signal may be used to activate/deactivate the entire bus or put it into a sleep, or low power mode. Preferably, the memory controller issues device identification cycles only at power up, and the device identifiers remain programmed when the bus is switched between normal operation and a low power state or sleep mode.

The memory controller uses an algorithm to determine when to issue chip ID cycles. The controller may need to make an initial count of devices, if the device count is not already known to the controller. Thereafter, during normal operation, all command packets from controller include an address field comprising a device ID for an individual targeted device.

The serial connection of a single enable signal for a channel comprising a plurality of memory devices is a unique solution to the initialization problem and is not known to have been practiced in prior parallel bus systems.

The aspects of the present invention provide a memory device, a system and methods in which a single serial enable signal per channel replaces unique enable signals for each individual memory device, significantly reducing the per channel pin count. Advantageously, this single enable link or connection can also be used to activate/deactivate the entire channel rather than to address individual devices for a given transaction. Commands on the common bus may be targeted to specific devices by insertion of an address field into an identification cycle of a command string.

These and other features of the present invention will become more apparent from the following description in which reference is made to the appended drawings, which are by way of example only.

### BRIEF DESCRIPTION OF THE DRAWINGS

Embodiments of the present invention will now be described, by way of example only, with reference to the following drawings:

FIG. 1A shows a block diagram illustrating a system comprising a host system including a processor, a memory controller and a memory system comprising a plurality of memory devices, to which embodiments of the present invention are applicable;

FIG. 1B shows a block diagram of a memory system including a plurality of memory devices and a controller connected to the plurality of memory devices via a common bus to which embodiments of the present invention are applicable;

FIG. 1C shows a block diagram of a memory system including a plurality of memory devices that are serially interconnected and a controller connected to the serially coupled memory devices;

FIG. 2 shows a schematic block diagram of a conventional parallel bus system comprising a plurality of memory devices interconnected to a multidrop parallel bus;

FIG. 3A shows a schematic block diagram of a system comprising a plurality of memory devices according to an embodiment of the present invention;

FIG. 3B shows a schematic block diagram of some elements of the controller of FIG. 3A;

FIG. 3C shows a schematic block diagram of some elements of a memory device of FIG. 3A;

FIG. 4 shows a timing diagram illustrating implementing of a command using a method of addressing memory devices of a system according to the embodiment shown in FIG. 3A;

FIG. 5A illustrates a status register read command for implementing the method in the system represented in FIG. 3A;

FIG. 5B shows a simplified view of the status register read command of FIG. 5A;

FIG. 6 illustrates a simplified view of program command for implementing a method of addressing memory devices of a system according to the embodiment shown in FIG. 3A;

FIG. 7 shows a block diagram of a memory device comprising a register according to an embodiment of the present invention;

FIG. 8 shows a block diagram of elements of memory device for use in a system according to the embodiment;

FIG. 9 shows a block diagram of a plurality of devices having a serial CEb link for a system according to the embodiment;

FIG. 10 shows a timing diagram illustrating how each memory device is individually accessed during initialization and in sequence for the purpose of programming its chip according to an embodiment of the present invention;

FIG. 11 shows a timing diagram illustrating how each memory device is individually accessed during initialization and in sequence for the purpose of programming its chip according to another embodiment of the present invention;

FIG. 12 shows a flow chart illustrating steps of a method according to an embodiment; and

FIG. 13 shows a flow chart illustrating further steps of a method according to the embodiment.

### DETAILED DESCRIPTION

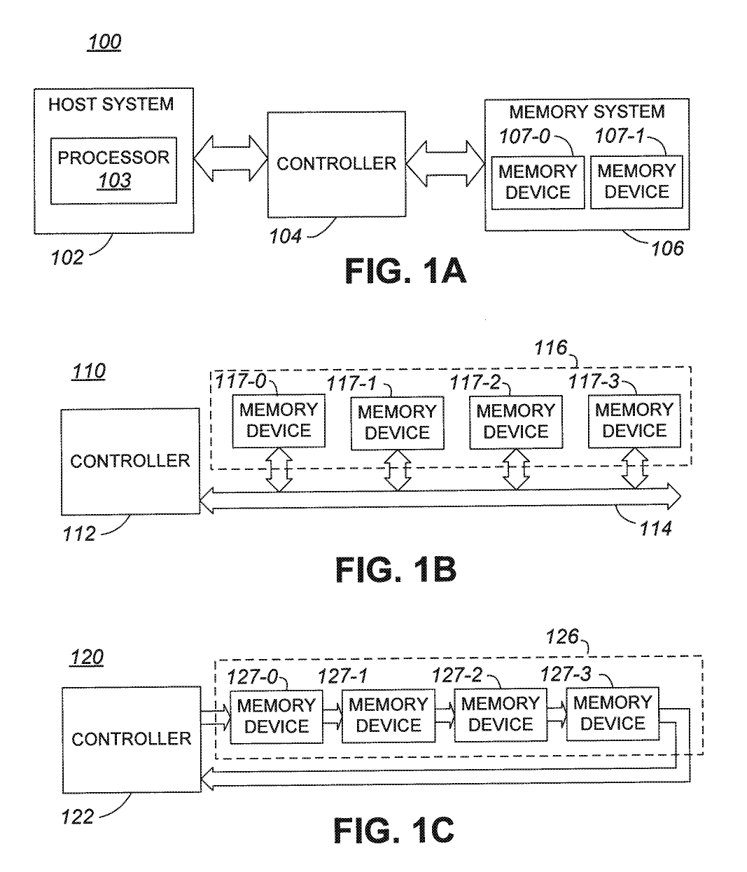

To form a large capacity memory system, as illustrated schematically in FIGS. 1A and 1B, multiple semiconductor memory devices, such as, for example, flash memory devices, are typically interconnected in parallel. Alternatively, memory devices can be serially interconnected as illustrated schematically in FIG. 1C. In such systems, the memory devices can be any type of flash memories, e.g., NAND, NOR, or AND type flash memories. Also, the memory devices can be random access memories, e.g., SRAMs, DRAMs, or other known types of memory devices, of the same or mixed type.

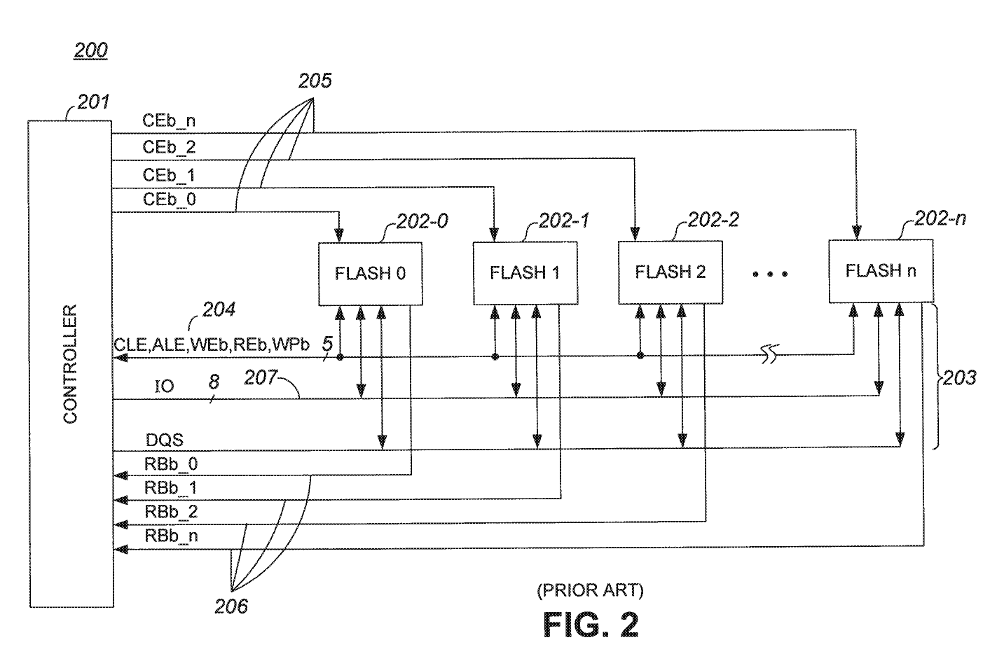

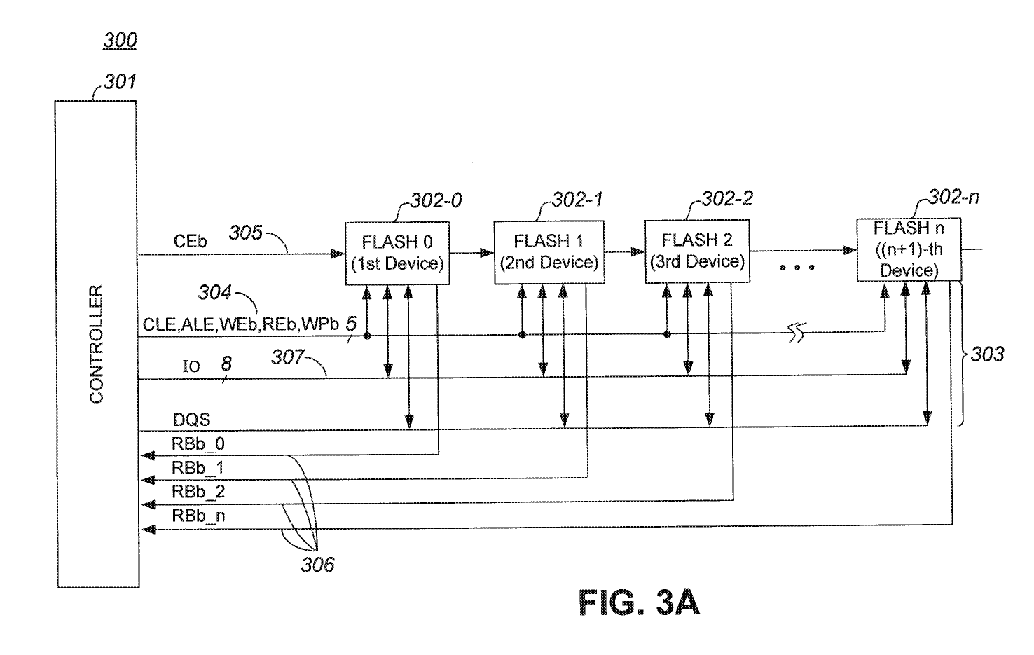

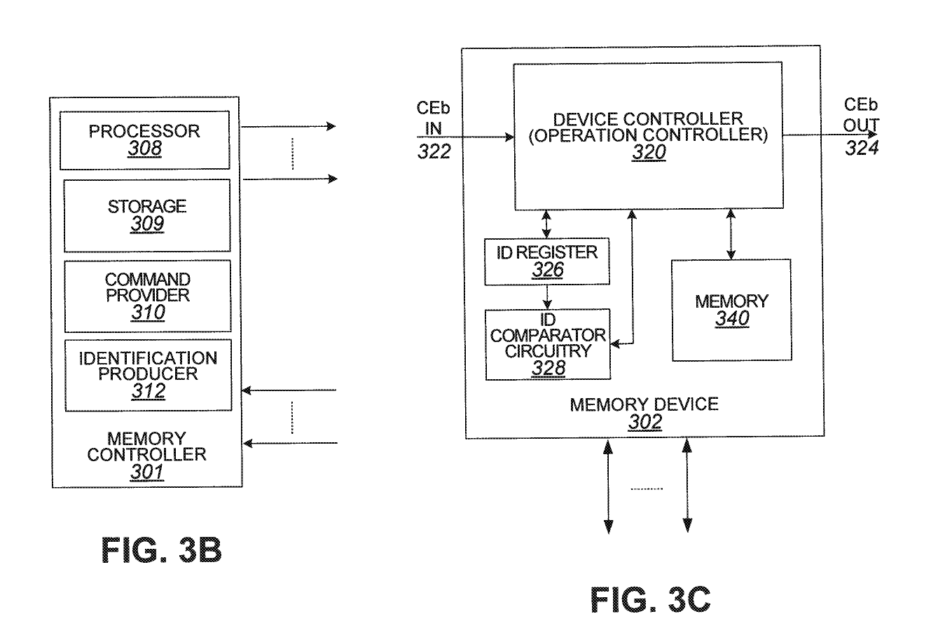

Systems according to embodiments of the present invention are directed to parallel bus memory systems. As a starting point, relevant details of a conventional parallel bus system will be described with reference to FIG. 2. By way of example only, a system according to an embodiment of the present invention comprising a plurality of flash memory devices will be described with reference to the FIGS. 3 to 13. This system provides for an enable signal as a single device or chip enable signal, CEb, for addressing a plurality of such memory devices, with reduced per-channel pin count.

Referring first to FIG. 1A, this figure illustrates an exemplary system 100 comprising a host system 102, comprising a processor 103, connected to a memory system 106 via a controller 104 for controlling the memory system. The memory system 106 comprises a plurality of memory devices, e.g., two flash memory devices 107-0 and 107-1, s as shown. The controller 104 receives requests from the host system 102 and translates the requests into commands that are interpretable by the memory system 106. The controller 104 also translates logical addresses into physical addresses of memory system 106 that are used by the host system 102 for storage and retrieval of data in memory banks of memory devices 107-0, 107-1.

FIG. 1B shows an example of a system configuration 110 comprising parallel memory device connections, i.e., a parallel bus architecture, wherein a controller 112 communicates with a memory system 116 comprising a plurality of memory devices, e.g., four flash memory devices 117-0 to 117-3 as illustrated, through a common bus 114. The controller 112 is coupled to an external system or controller like the host system 102 as shown in FIG. 1A. The controller 112 uses the common bus 114 to transfer data into and out of the memory devices 117-0 to 117-3. In a particular example, only one designated flash memory device is asserted at a time with this configuration, by asserting a chip enable signal CEb, which is unique for each device.

For comparison, FIG. 1C shows an alternative system configuration 120 wherein the memory system comprises serially connected memory devices, i.e., serial memory architecture. In such an arrangement, a controller 122 is coupled to a memory system 126 comprising a plurality of memory devices (e.g., four flash memory devices 127-0 to 127-3) that are serially interconnected in a loop or ring configuration. Each of the memory devices 127-0 to 127-3 is serially coupled so that data and commands coming into the memory system must pass through every other memory device to reach the last device 127-3 in the series connection. Thus instead of a CEb signal to select a target device for a command, each device must be assigned a device ID, and each serial command string must contain a device ID of the targeted device. The controller 122 is coupled to an external system or controller like the host system 102 as shown in FIG. 1A.

When multiple memory devices are interconnected, the controller manages flow between individual memory devices and interfaces for storing data, accessing data and manipulating data in the system. A command structure is used by the controller to provide requests to individual memory devices storing data. The command structure is dependent s on the configuration of the interconnected memory devices and can impact performance of the system. Conventionally, in a system as illustrated in FIG. 1B, when individual devices are in communication with the controller 112 via a common bus, only specific one or ones of the individual devices may be asserted at any given time.

The internal structure of a flash memory device, such as a NAND flash memory device and typical command structures for operation of memory systems comprising flash memory devices, is described in detail, for example, in PCT International Publication No. WO2008/022434A1 entitled “Modular Command Structure for Memory and Memory System”. This application, and related applications, provides a detailed description of the internal memory bank structure and internal operations of such memory devices for data storage and retrieval. The embodiments of the present invention relate to initial cycles of a command string for selectively addressing individual memory devices and other subsequent operations.

Conventionally, for a system with a common bus interconnection, e.g., the system as illustrated schematically in FIG. 2, a controller 201 is coupled to a plurality of (N=n+1) memory devices 202-0, . . . 202-n, i.e., flash memory devices labelled FLASH 0 to FLASH n, via a multidrop parallel bus 203. Commands generally enter a flash memory device 202-n via the assertion of different pins on the external packaging of the chip, where different pins may be used to represent different commands received from corresponding pins on the controller 201.

In the system shown in FIG. 2, signals 204 that are common to all devices on the bus include Command Latch Enable (CLE), Address Latch Enable (ALE), Write Enable (WEb), Read Enable (REb), Data Strobe (DQS) (for some systems) and Write Protect (WPb) signals. Signals unique to each device on the bus include Chip Enable (CEb) signals 205 and Ready/Busy (RBb) signals 206. Commands, addresses and data 207 are multiplexed via common Input/Output pins, i.e., IO[x:0] 207. Each of the signals is a digital signal having transitions of logic levels that are rising and falling edges.

The I/O pins [x:0] are used to receive a command, an address and input data for a write operation and output data for a read operation. The CEb signal is used to individually activate a particular memory device(s), i.e., CEb_n enables/disables device. The WEb signal is used to control a write operation, and for example, the targeted device latches a command, an address or data at a rising edge of the WEb signal. The CLE signal is used to receive a command signal, e.g., if the CLE is logically high on the rising edge of the WEb signal, the memory device latches a command, i.e., identify a signal input as a command, and store the input in a command register. Similarly, if the ALE signal is logically high on the rising edge of the WEb signal, the device latches an address. WPb is used to protect the device from inadvertently being read or written. The output RBb is used to report on a ready or busy status of the device to the controller 201.

Thus, each memory device comprises a number of pins I/O [x:0], e.g., eight, for is inputting and outputting data, pins for receiving each of CLE, ALE, WEb, REb, WPb signals respectively, CEb signal input pins and pins for outputting RBb signals. The controller 201 requires a corresponding set of pins. For the (n+1) unique CEb signals and for the (n+1) RBb signals, it is apparent that in such an arrangement each memory device has an individual CEb input (e.g., CEIb_n) and a memory system with N memory devices per channel requires that the controller 201 comprise a corresponding number (n+1) of CEb and of RBb pins per channel.

A system 300 according to a first embodiment of the present invention, as shown schematically in FIG. 3A, comprises a plurality of memory devices 302-0, 302-1, 302-2, . . . , 302-n coupled to a multidrop parallel bus 303 and requiring only a single CEb signal 305 per channel, for reduced per channel pin count. As illustrated in FIG. 3A, the system 300 comprises a controller 301, and a plurality of (N=n+1) memory devices: a first device “FLASH 0” 302-0, a second device “FLASH 1” 301-1, a third device “FLASH 2” 301-2, . . . , a (n+1)-th device “FLASH n” 302-n. The controller 301 coupled to an external controller or host system (not shown) provides signals 304 that are common to all devices on the bus. The signals 304 include Command Latch enable (CLE), Address Latch Enable (ALE), Input/output IO[x:0], Write Enable (WEb), Read Enable (REb), Data Strobe (DQS) and Write Protect (WPb) signals; commands, addresses and data are multiplexed via common I/O pins 307; and Ready/Busy (RBb) signals 306 are unique to each device.

However, the system 300 shown in FIG. 3A differs from a conventional system as shown in FIG. 2, in that for a channel comprising (n+1) memory devices 302-0 to 302-n, a single CEb signal 305 is serially coupled from the controller through each of the N memory devices. That is, each memory device comprises a serial CEb input (CEIb) and a serial CEb output (CEOb). The single CEb signal 305 from the controller 301 is coupled to the CEb input on the first device 302-0, and then from the CEb output of the first device 302-0 to the CEb input of the subsequent device (i.e., the second device 302-1). Similarly, the CEb output of the second device 302-1 is coupled to the CEb input of the subsequent device (i.e., the third device 302-2), so that the CEb signal is propagated serially from the first device 302-0 to the last device (i.e., the (n+1)-th device) 302-n. In this arrangement with a serial CEb link, the single CEb signal 305 is used per channel to address any one of the (n+1) memory devices. Thus, with the CEb signal, it is possible to enable or disable all devices on the entire bus (channel) or put it into a “sleep” or low power mode.

To enable a single CEb signal to address an individual memory device, e.g., 302-n, a device identifier, i.e., a device ID, chip ID word or cycle, is added to each command that needs to target a unique device. On initialization of the system, e.g., after power-up, each flash memory device on a channel is assigned a unique device identifier, i.e., a device ID or chip ID, by the controller 301 and then the controller 301 uses the device IDs to address individual memory devices during normal operation. To do this, an address field containing a device identifier is added to each command string.

The controller 301 thus requires a way to assign each device a device identifier, such as a unique address or chip identifier. Correspondingly, each memory device needs a way to determine, based on its assigned device identifier, if it is the targeted device to be addressed by a command. As illustrated in the simplified block diagram in FIG. 3B, the memory controller 301 comprises a processor 308 and storage elements 309 for storing program instructions and data. The controller 301 also comprises command circuitry or provider 310 configured for generating commands, e.g., a flash command engine, an error correction code manager and flash device interface, and identification circuitry or provider 312 configured for generating and assigning an identifier for each memory device. For each command that is to be targeted to an individual memory device, the command circuitry 310 is configured to insert a respective device identifier into an address field of each command string.

As represented in the simplified block diagram in FIG. 3C, each memory device 302 comprises a device controller 320 (alternatively referred to as an operation controller) and memory 340, i.e., a plurality of memory banks and associated circuitry. The memory device 302 has a serial CEb input 322 and CEb output 324. The memory device 302 further comprises a storage element, such as a register 326 for storing an assigned device identifier (ID), and control circuitry, such as ID comparator circuitry 328, configured for extracting a device identifier from the address field of a command string, determining if there is a match with the stored assigned identifier, and if there is a match result. When there is a match result, the targeted memory device further processes the command, or otherwise waits for another command.

In a method of assigning device identifiers according to an embodiment, the controller 301 takes advantage of the input-to-output delay of the common CEb signal that passes serially through each memory chip 302 to assign a device ID dynamically. As will be explained in detail below, the difference between the times when each device responds to the transition (e.g., the falling edge) of CEb as it passes serially through the (n+1) devices is used to assign each successive chip with a unique device ID.

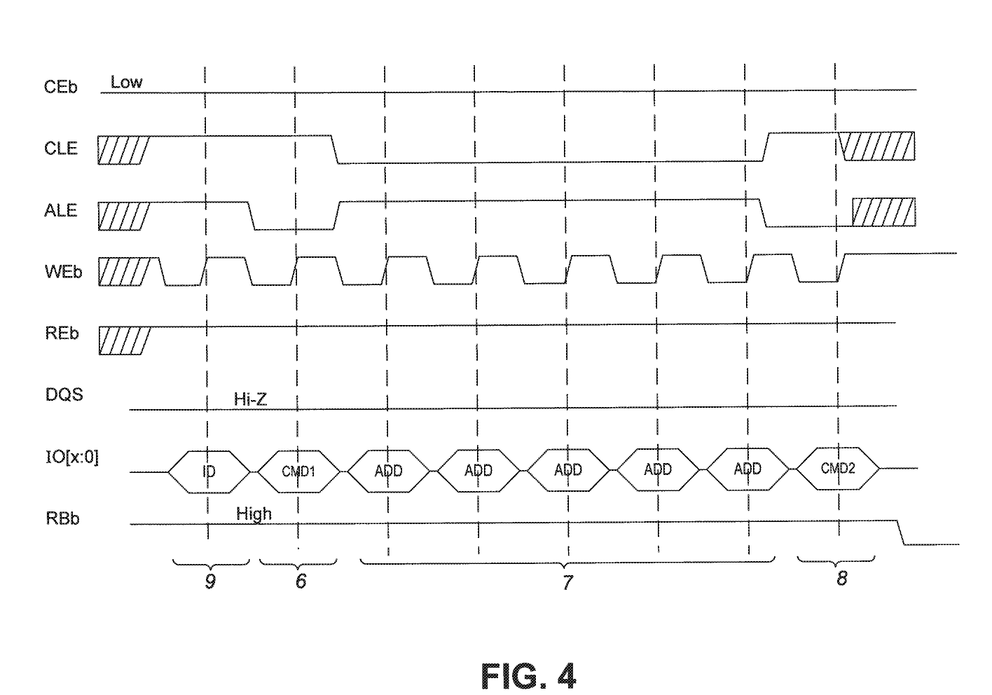

The operation of the system according to the embodiment for typical flash transactions will now be described with reference to FIGS. 4 to 13 to highlight differences in the structure and operation relative to a conventional parallel bus memory system which requires unique CEb signals for respective individual memory devices.

Flash Transactions

Page Read Command

FIG. 4 illustrates a command using a method of addressing memory devices of a system according to the embodiment, using a single CEb signal. In this particular example, the command is a page read command issued by the controller to a device on the memory channel, i.e., what the controller asserts to a flash device. The page read operation can be broken into four steps or cycles: a device ID or chip ID cycle (9), command 1 (6), array address (7), and sometimes, or optionally, command 2 (8). This command string or sequence is provided by way of example only. Commands with other sequences are s possible. The command 1, array address and command 2 cycles or steps labeled 6, 7, and 8, respectively, are typically found in conventional flash command sets. The device identification cycle (i.e., Device ID or Chip ID step) 9 is introduced to enable a system having a single CEb signal to address individual memory devices on the channel.

Since a target device must be specified for most types of operations, instead of using unique CEb signals for each device, the additional identification step 9 is inserted into all command packets that are device specific or have need of target device identification. The additional identification step 9 supplies the device ID. When the bus is idle, all memory devices 302-0 to 302-n on the channel are sampling the bus, i.e., listening for a new command. When a new command sequence or transaction is received, all devices latch is the device ID word (9). Once the device ID is latched, the device (e.g., the ID comparator 328 shown in FIG. 3C) compares the received device ID with the stored device ID (e.g., the ID stored in the ID register 326 shown in FIG. 3C), and only the target device, whose own chip ID matches the one sampled on the bus, continues to participate in the transaction to process the page read command. All other devices ignore the rest of the operation, because of no much.

As illustrated in FIG. 4, the chip ID cycle 9 is delimited by the assertion of both CLE and ALE in the first step of the transaction. That is, a new transaction is indicated when CLE and ALE are high, and the device latches in the device ID on the rising edge of WEb. Each device samples the bus, when CLE and ALE are asserted to determine if it is target of the current transaction. If the device ID matches the stored device ID, the targeted device continues to latch in command 1, step 6, and address words until the completion of the operation, step 7. If there is no ID match, the device simply ignores bus activity until the next time CLE and ALE are both asserted. As will be appreciated, this signal combination is described by way of example only Other signal combinations may be used to delimit the device ID word. What is important is that there is a unique combination of signals that indicate the identification cycle, i.e., identify when a chip ID word is being driven onto the bus and to indicate the beginning of a transaction.

As illustrated, the first cycle, or step 9, of a given operation is an ideal place to transmit the device ID. Alternatively it could also be transmitted later in the operation, i.e., s in a second or subsequent cycle, e.g., after the command 1 cycle 6, and before the first cycle of the array address cycle 7.

Status Register Read

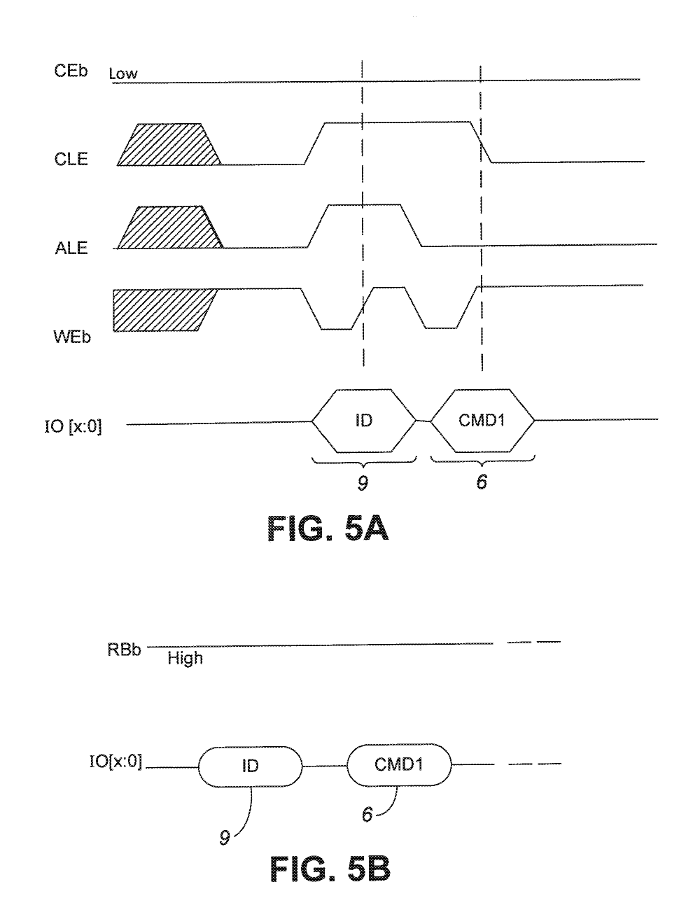

FIG. 5A shows the components of a status register read command. Similar to the command sequence shown in FIG. 4, when CLE and ALE are high and on the rising edge of WEb, the command sequence is commenced with a device ID cycle, 9, as described above, and then a command 1 cycle, 6. Although the command comprises later parts (not shown), the device ID cycle enables individual devices to be targeted when using a single CEb signal. FIG. 5B shows a simplified view of the status register read command showing only the chip ID cycle 9 and the command 1 cycle, 6. In response to a match is result, the addressed or target device processes the status register read command.

Page Program Command

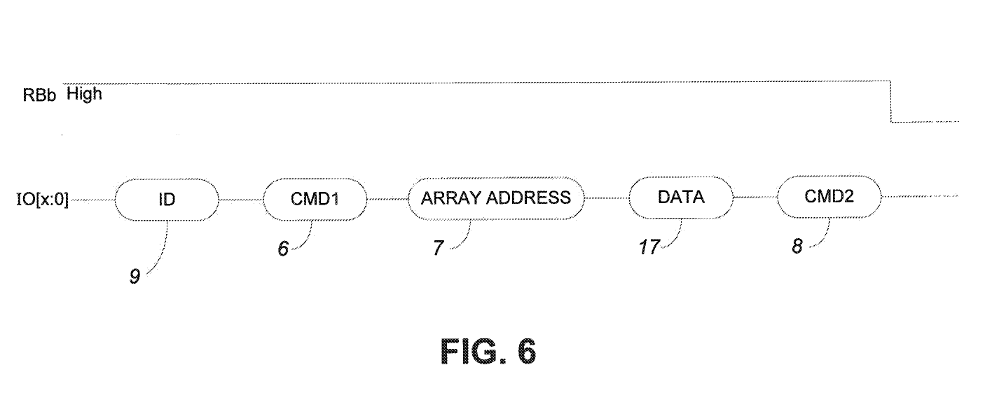

Correspondingly, FIG. 6 shows a simplified view of components of a program command comprising an address and data. The command sequence is begun with a device ID cycle 9 as described above, followed by a command 1 cycle 6, array address cycles 7, data cycles 17, and a command 2 cycle 8. In response to a match result, the target device defined by the ID (9) processes the page program command and the data (17) is written into the memory array in accordance with the array address (7).

Device Identification Cycle

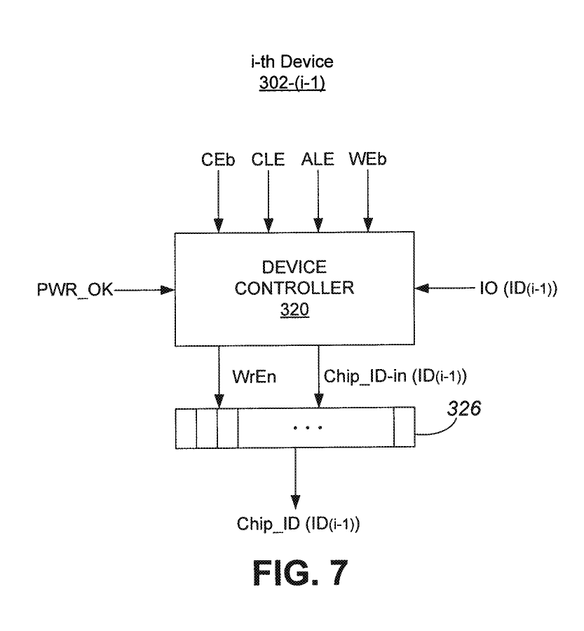

Each memory device for a system according to an embodiment of the present invention comprises a serial CEb input 322 and a serial CEb output 324 and each device on a channel is assigned a unique device identification, device ID or Chip ID, to enable operation using a single CEb signal per channel. In normal operation, a command structure is used including a device identification cycle 9 that extracts a device identification from an address field that is added to each command which is to target an individual memory device. These elements of the device and the device ID cycle will now be described in more detail with references to FIGS. 7, 8 and 9.

Device ID Register and Initialization

As described above, each device samples the bus when CLE and ALE are asserted, to determine if it is a target of the current transaction. If the device ID latched in by the device matches a stored device ID, the device will be a target device and the targeted device participates in the transaction, otherwise the device will ignore bus activity until the next time CLE and ALE are both asserted. As illustrated in FIG. 7, which shows a block diagram of some elements within a single flash memory device 302 (e.g., the i-th device 302-(i−1)), signals for PWR-OK, CLE, ALE, WEb, together with the CEb signal are input to the flash memory controller 320 of the memory device 302. For the purpose of device ID comparison, i.e., to determine if the device ID contained in the asserted command matches the device ID, each device must be assigned a unique device ID and each device must store it locally. Therefore, as shown in FIG. 7, each flash device 302 is provided with a register 326 corresponding to the ID register 326 shown in FIG. 3C, which is used to store its device ID. Shortly after power-up, the device listens for a device ID assignment from the controller 301, and a unique device identification, i.e., a device ID or chip ID (Chip_ID-in) (e.g., ID(i−1)) is received from the controller on the data bus in response to a write enable signal WrEn, and stored in the device ID register 326 of the flash device by the device controller 320, as indicated in FIG. 7. The devices 302-0 to 302-n on the channel are sequentially accessed for this device identification or ID assigning process. In a case of the initial ID being “0”, devices 302-0, 302-1, 302-2, . . . , 302-n are assigned “0”, “1”, “2”, . . . , “n”, respectively. Such IDs “0”, “1”, “2”, . . . , “n” are sequentially generated and output by the controller.

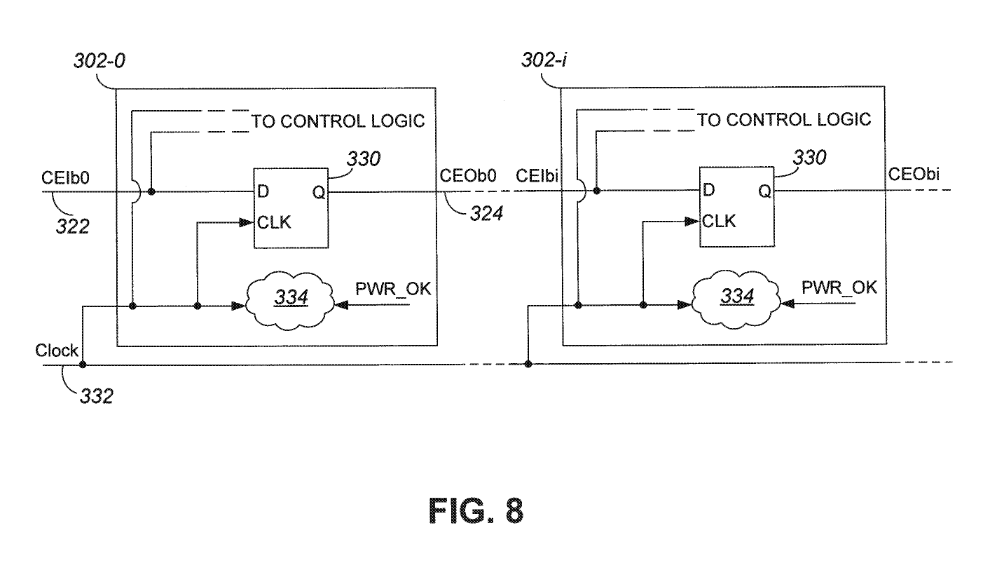

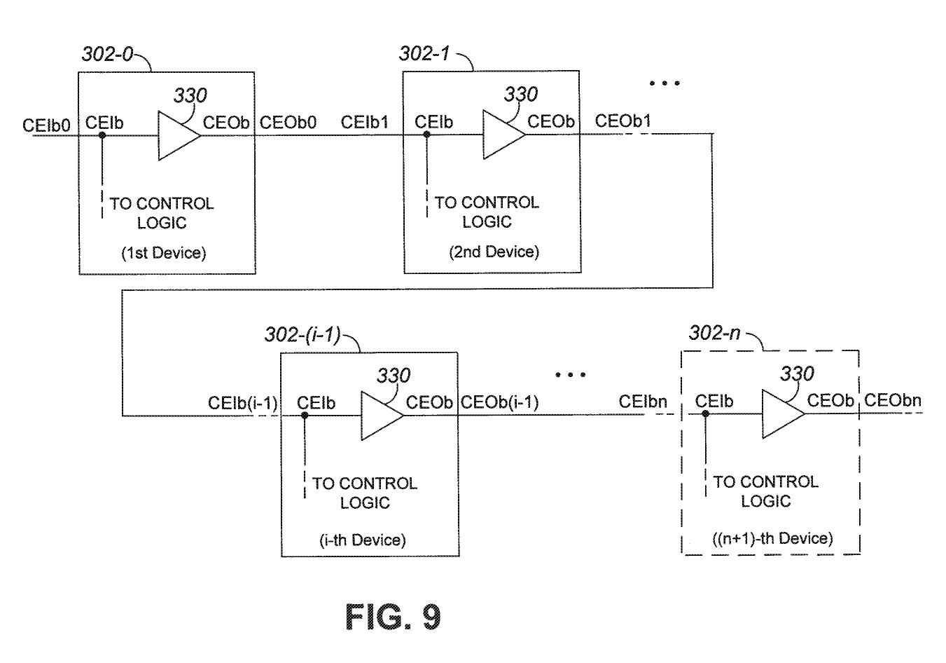

To accomplish this, each flash device 302 is equipped with a serial CEb input (CEIb) 322 and a serial CEb output (CEOb) 324 as shown in FIG. 8, so that a plurality of (n+1) memory devices 302-0 to 302-n are serially coupled to the common CEb signal output from the controller as shown in FIG. 9. Within each memory device 302, CEIb and CEOb are connected internally via a delay element 330, i.e., a buffer providing a pre-defined time delay of a known amount, t_{CID}. In this particular example, each of the delay elements 330 is a D-type flip-flop that receives a parallel clock signal 332 “CLK” from the controller. The clock signal 332 and a power-up response signal PWR_OK are fed to a power-up response circuit 334 that is part of the device controller 320. The clock signal 332 and the CEIb are fed to control logic circuit (not shown) that is part of the device controller 320.

For example, the buffer delay is assigned to a clock period of a suitable clock cycle, which is typically the normal clock cycle. Within each memory device, the chip enable input signal CEIb to each device is coupled to control logic circuitry of the device controller 320 (FIG. 3C) to enable or disable the memory device. It is also coupled through internal circuitry comprising the delay buffer 330 to the chip enable output, e.g., CEOb which in turn is serially coupled to the chip enable input CEIb of the subsequent memory device in series, and so on, as shown in FIGS. 8 and 9. For example, the CEb output of memory device 302-0 CEOb0 is fed as the CEb input CEIb1 of the subsequent memory device 302-1. The chip enable output of the last, or (n+1)-th device is left open or terminated. In embodiments described herein it is not intended that the CEb link is configured as a loop.

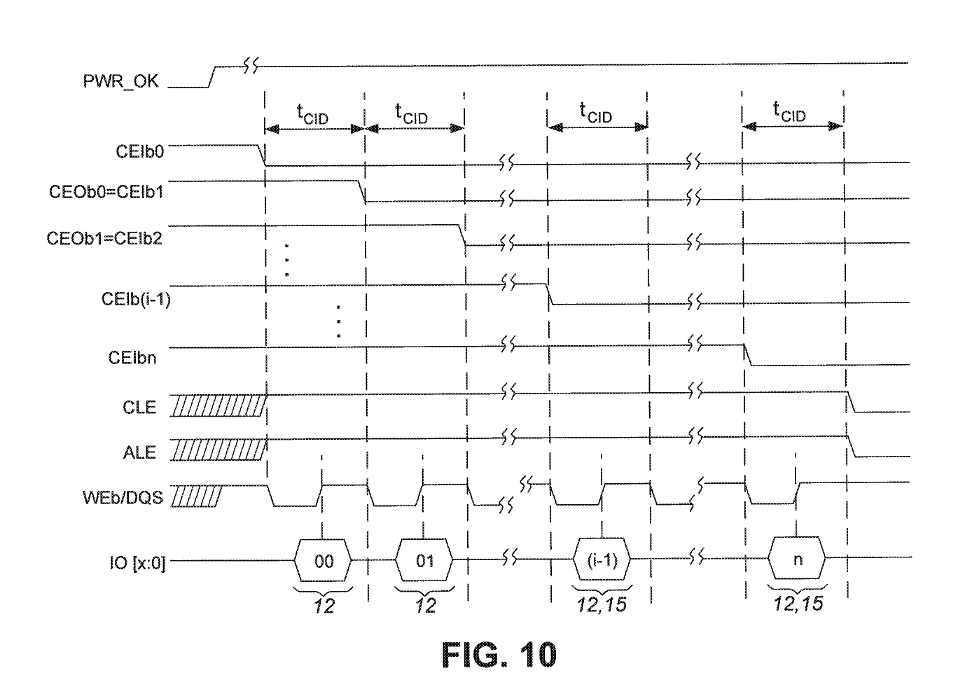

FIG. 10 shows a timing diagram illustrating how each of flash devices 302-0 to 302-n is individually accessed during initialization and in sequence for the purpose of programming its chip ID in its chip ID register. A particular signal indicating that the device is being initialized following power-up, in this case the combination of the rising edge of PWR_OK followed by the falling edge of CEb, indicate that this device is being addressed for a special initialization operation on the bus. Since CEb is serially propagated through a delay buffer on each chip, each chip will see this event, i.e., the falling edge of CEb, within its own unique time window of length corresponding to the pre-defined delay t_{CID}, as illustrated in FIG. 10. The unique time window, i.e., during which a particular device is enabled in sequence, provides a way to address each device individually for the chip ID initialization operation (device identification cycle) 12. During this time window, on the bus IO [x:0], the controller drives the chip ID initialization command (12 in FIG. 10) for the respective memory device lasting a duration t_{CID}. In the embodiment, an i-th memory device having a device identifier of (i−1) is activated by CEIb(i−1), i being a variable of 1, 2, . . . , n, (n+1). The activated i-th memory device is initialized with its unique identifier (i−1) during a particular time window starting at the time the CEb signal has taken to pass through the preceding delay buffers of devices 0 to (i−1). Thus, the delay of the CElbi for the i-th device is (i−1)×t_{CID}.

Thus each memory device 302 is individually enabled and programmed with its respective unique identifier, in sequence, i.e., pseudo-synchronously.

The step of assignment of a device identifier is needed only once after power up at the initial operation phase. If the signal CEb transitions to low sometime during operation, e.g., to put the channel into a low power state, and then transitions back to high, e.g., to take the channel out of a low power state, the channel will not need to go through the chip ID initialization process again. The chip ID is already programmed into the chip ID register of each device and is persistent until the channel is powered down. Thus the controller, and the chip ID controller, within the memory device provide instructions to carry out chip ID initialization only after power-up. The signal PWR_OK is used to keep track of this condition within the flash memory device. The controller similarly uses a power status of the channel to track when to carry out initialization and assignment of device IDs.

If the controller 301 or firmware knows how many memory devices, e.g., (n+1) devices, are populated on the channel, it will issue a series of (n+1) chip ID commands, i.e., one for each device 0 to (n+1) (i.e., step 15 in FIG. 10).

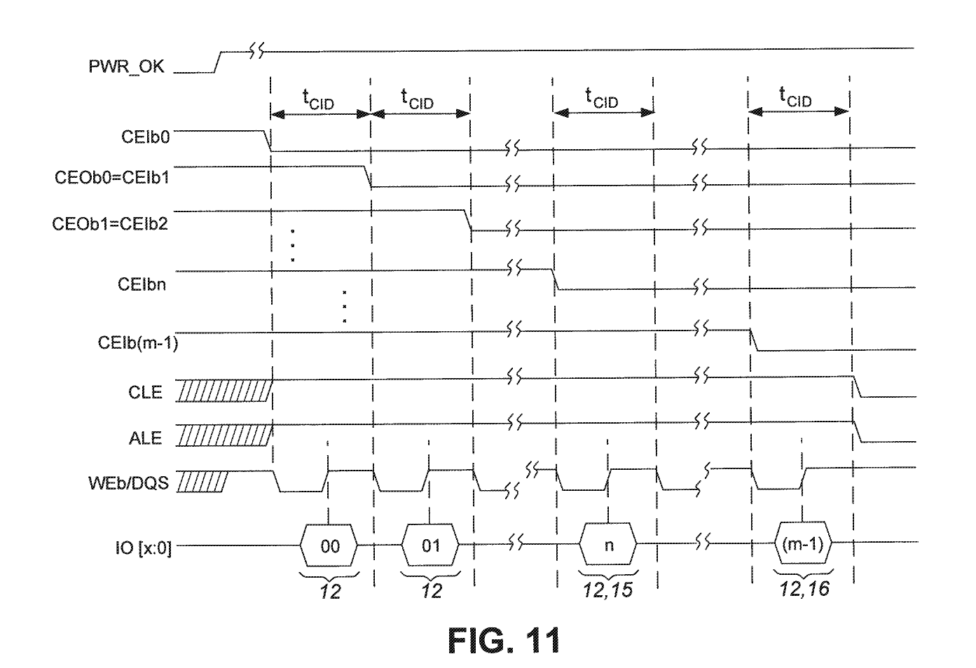

If the controller or firmware has no foreknowledge of the channel population, it will issue a series of chip ID commands (0 to m) that is guaranteed to be as long as the maximum allowable population on the channel (i.e., step 16 in FIG. 11).

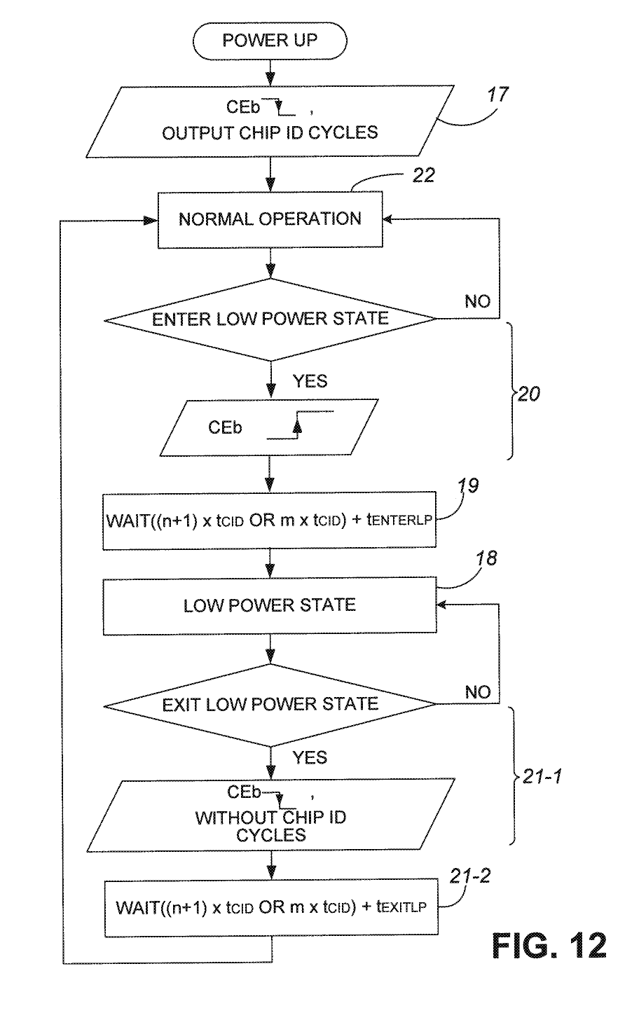

FIG. 12 shows a flow chart explaining an algorithm that the controller uses to determine when to issue chip ID cycles (step 17 in FIG. 12), i.e., because the devices are being initialized, and when CEb should be de-asserted for some other reason, like entering a low power state (step 18), without issuing chip ID cycles. Thus, in an initialization phase, i.e., on power up or soon after power up, when PWR_OK transitions to high and CEb goes low, the controller will output the chip ID cycles (step 17), as described above, to assign device identifiers to each memory device 302-0 to 302-n.

The controller will then resume normal operation, step 22, until it is required to enter the low power state, step 18. Then CEb will be asserted, i.e., transitions to high (step 20), to disable all devices on the bus and put them into a low power or sleep mode (step 18).

Since CEb is serially coupled through each device and its corresponding buffer having a time delay of t_{CID}, there is an additional amount of time that the channel takes to completely respond to any transition on CEb compared to a conventional design where CEb is connected to each device in parallel. For (n+1) devices (i.e., i=1 to i=n+1) as shown in FIG. 9, and illustrated in step 19 of FIG. 12, this additional amount of time can be expressed as:

(n+1)×t_{CID} (a)

or

m×t_{CID} (b)

where (n+1) is the number of devices populated on the channel and m is the maximum number of devices allowed to be populated on the channel. Thus at step 19 of FIG. 12, the controller waits (n+1)×t_{CID} or m×t_{CID}, so that the CEb signal has time to propagate through each device in the serial link, plus an additional time t_{ENTERLP}, to allow sufficient time for the last device to enter low power mode.

Similarly, when the controller takes the bus out of low power mode, step 20 of FIG. 12, back into normal operation, when the CEb signal transitions to low, at step 21-1, the controller waits (n+1)×t_{CID} or m×t_{CID} to allow the CEb signal to propagate through each memory device plus an additional time t_{EXITL}, to allow time for the last memory device to exit low power mode (step 21-2). The controller then resumes normal operation, step 22, during which all memory devices are enabled (CEb low) and during which commands on the bus comprise an address field including a device identifier to target an individual memory device that is to participate in a transaction.

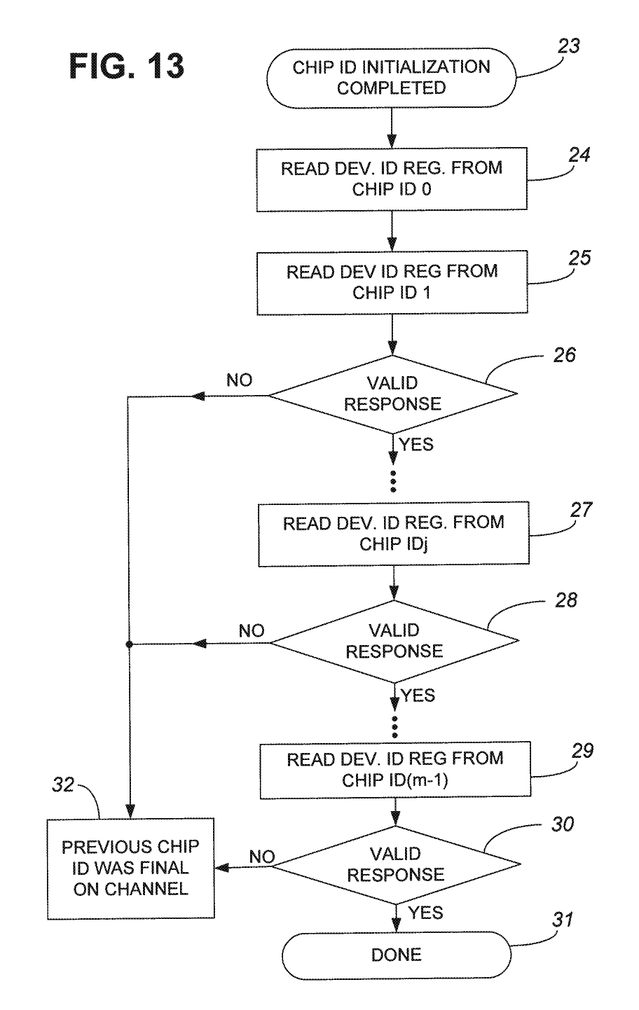

After step 17, and before normal operation, step 22, once all chip IDs have been assigned, optionally, the controller goes through a discovery process, as shown in FIG. 13, to determine how many memory devices are populated on the channel and/or to confirm or validate that all devices have successfully stored an assigned device identifier. To do this, after the chip ID initialization step 17 is completed, at step 23 the controller issues a device information register read command, or equivalent, on the parallel bus, to each of the chip IDs in the entire allowable range of chip ID in sequence (steps 24 to 29). In each memory device, the flash controller 320 reads the device identifier from the register 326 and sends a response to the controller 301 (steps 24, 25, 27, 29). If there is no valid response from a chip ID (the negative determination at step 26, 28, 30), then the previous chip ID is determined to be the last one on the channel (step 32). Therefore, the controller can detect the number of connected devices is determined and the ID assignments of the first to last devices are valid, from the ID value or information on the determined last device. At step 24, the assigned device identification ID0 of the first device is read. At step 25, the assigned device identification ID1 of the second device is read. If no ID reading from the second device (the negative determination at step 26), the response is not valid and thus the previously read ID (ID0) is final. The number of devices is one (=ID0+1). If the response at step 25 is valid (the positive determination at step 26), the assigned IDs of the subsequent devices are sequentially read. The IDj of the (j+1)-th device is read (step 27). In the case where the response from the (j+1)-th device is invalid (the negative determination at step 28), the previously read ID, ID(j−1), of the j-th device is final and therefore, the number of the device is j. Thus a count of devices on the channel can be obtained. Upon reading the device identifier of the m-th device (the positive determination of step 30), the read device identification of the m-th device is determined to be the device ID, ID(m−1), of the last device, and thus, the number of devices is m. The determination of the device number or the validation of the device identification assignment is completed (step 31).

### SUMMARY OF THE EMBODIMENTS

The solution described herein can substantially reduce the pin count on a flash memory channel using a parallel bus architecture. By assigning an address or identifier to each device and adding an address field, i.e., a device ID, to each command, a single common CEb signal, i.e., using a single CEb pin per channel, can be used to address multiple memory devices. The need for a set of individual unique CEb signals to address each device is eliminated, thereby reducing the per channel pin count of the controller.

In particular, in a system comprising a controller and a plurality of memory devices which are interconnected in parallel via a multidrop data bus, each device is provided with a serial CEb input and serial CEb output and a serial connection or link is provided for assertion of a single CEb signal, while commands are implemented using a conventional parallel bus interconnection configuration, by adding an address field comprising a device identifier to each command string.

For example, on a channel populated with eight memory devices the pin count of the controller is reduced by 7 pins. If there are also 10 channels in the flash memory system, then the overall pin count overhead of the controller is reduced by 70 pins.

A particular method for assignment of a device identifier is described above which can be practically implemented with minimal overhead using the serial CEb link, and using a delay element such as a delay buffer or time delay circuitry with a predetermined delay between the serial CEb input and serial CEb output of each memory device, together with a register for storing an assigned device identifier. During the device ID assignment or initialization phase, the delay element between the CEb input and CEb output of each memory device, provides sufficient delay t_{CID} that as the CEb signal transition, e.g., the falling edge of CEb, propagates through the series of memory devices, the memory devices are, in effect, individually addressed in sequence, while a sequence of chip identification cycles are driven onto the bus at intervals that fall within a respective time window t_{CID} for each device, so each memory device can latch in its respective device ID in turn.

For normal operation, the device identifier for the target device is added to the command string which is fed to the target device via the parallel data bus. That is, a serial CEb connection for asserting a CEb signal to enable or disable all devices on the entire bus. Commands targeted to individual devices are asserted using a conventional parallel bus configuration by adding a device identifier to an address field of each command string, e.g., in an identification cycle of each command string.

Conveniently, this configuration of multiple memory devices interconnected with a parallel data bus and a single serial CEb link also allows for the single CEb signal to be used to activate or deactivate the entire bus, e.g., put it into a “sleep” or low power mode, e.g., for power saving.

### Alternative Embodiments

Other alternative methods can be used for assigning a device identifier. For example, another method for assignment of a device identifier, such as a chip ID or chip address is disclosed in PCT International Publication no. WO2007/134444, entitled “Apparatus and Method for Establishing Device Identifiers for Serially Interconnected Devices”, the teachings of which are incorporated herein by reference in their entirety. For memory systems having a serial bus architecture, operations are selected using command strings that are fed serially to memory devices that are serially linked. The command strings typically contain a command that represents the operation to be selected as well as other parameters and to select the device on which the command is to be performed each serial command string contains a device identifier. Thus other methods are known for assigning a device identifier.

In conventional devices, ID assignment of an identifier is typically performed using additional pins to make a logic combination such as 000, 0001, . . . , 1111. That is, the device ID is hardwired, e.g., using additional pins, which is undesirable for the present application. Another approach is to provide a device with a pre-assigned device ID, e.g., hardwired into the device. However, if a large volume of devices is produced, the size of the device ID may be large, leading to increased complexity in managing device IDs. Reclaiming device IDs that are no longer used may add to complexity. Thus it is preferable to dynamically assign a device ID to each device, for example as disclosed in the present application.

In PCT International Publication no. WO2007/134444, a device controller is disclosed comprising an device ID generator such that a first device in a serial interconnection is assigned a first ID, e.g., an N bit ID, which is incremented or decremented by one, for example, using an N bit adder or N bit subtractor, for each successive device in a series connection of a plurality of devices. The device ID is stored locally by each device, e.g., in a register. Each device also comprises an ID comparator to compare a received device ID with the stored device ID to determine if there is a match. Such as system therefore provides for serially assigning a device identifier, and then using the device identifier to target a device to participate in a transaction in a serial data connection.

In contrast, in systems according to the embodiment described above, identification circuitry of the controller, e.g., identification circuitry 312 of the controller 301 in FIGS. 3A and 3B, produces device identifiers and these identifiers are input to individual memory devices through a command on the parallel bus, or an ID line, during a device ID initialization cycle, e.g., after power up. Subsequently during normal operation, a device identifier is added to each command on the parallel bus to target an individual device.

Device identifiers are implemented in a parallel data bus configuration to enable operation with a single serial CEb link per channel, thereby reducing the pin count relative to conventional implementations with individual CEb signals for each device. The device identifier can be any suitable type of address, device identifier or chip ID.

The implementation of a parallel data bus configuration with a single serial CEb link per channel provides a practical solution for flash memory systems and other memory systems because it is not necessary to add additional logic to each flash device. Known bus protocols exist, which will support a serial CEb link with a parallel data configuration, as described herein.

In contrast, implementation of RBb signals using a serial RBb link is more complicated. A similar approach for reducing per channel pin count for RBb signals would be more complex and require adding logic to each flash device. Thus, while it is feasible, other approaches for reducing RBb pin count may be preferred.

In embodiments described above, the memory devices are non-volatile memory devices that are for example flash memory devices. Flash memory devices are, for example, NAND flash memory devices, AND flash, NOR flash or other flash memory devices. The memory devices are alternatively volatile memory devices that are for example random access memories such as DRAMs, SRAMs, MRAMs. The memory devices may be other types of non-volatile and/or volatile memory devices. In embodiments described above, the elements such as devices and circuits are shown connected to interconnected to each other as illustrated schematically in the Figures for the sake of simplicity. In practical implementations, some elements may be coupled or connected directly to each other or indirectly through other elements.

It will also be apparent that although embodiments are described using specific combinations of command, address and data signals by way of example only, e.g., assertion of CEb on the falling edge of the CEb signal, and commencement of an initialization cycle for assigning device IDs immediately following a rising edge of PWR_OK followed by a falling edge of CEb. In alternative embodiments, other suitable signal combinations can be used, and a transition on a rising edge and/or a falling edge of a signal can be used for assertion.

In the embodiments described above, the device elements are connected to each other as shown in the figures, for the sake of simplicity. In practical applications of the present invention to an apparatus, devices, elements, circuits, etc. may be connected directly to each other. As well, devices, elements, circuits etc. may be connected indirectly to each other through other devices, elements, circuits, etc., necessary for operation of the apparatus. Thus, in actual configuration, the circuit elements and devices are directly or indirectly coupled with, or connected to, each other.

Alterations, modifications and variations may be made to the particular embodiments by those of skill in the art. Thus, although specific embodiments of the invention have been described and illustrated in detail, it is to be clearly understood that the same is by way of illustration and example only and not to be taken by way of limitation, the scope of the present invention being limited only by the appended claims.

What is claimed is:

1. A system comprising a controller and a plurality of (N) memory devices, N being an integer greater than one, the plurality of memory devices being
interconnected to the controller on a common bus comprising parallel links, and
interconnected in series by a serial chip enable link from a single enable output of the controller.

2. The system of claim 1 wherein the plurality of memory devices comprises at least first and second memory devices, each of the first and second memory devices comprising a serial enable input and a serial enable output,
the enable input of the first memory device being coupled to the enable output of the controller, and
the enable output of the first memory device being coupled to a enable input of the second memory device in the series, for providing single enable signal from the controller for enabling or disabling each of the plurality of memory devices.

3. The system of claim 1 wherein
each of the plurality of memory devices comprises a serial enable input and a serial enable output, and
the serial enable link connects each of the plurality of memory devices in series, a enable input of a first memory device coupled to the enable output of the controller, and each enable output of the first memory device and of other memory devices coupled respectively to an enable input of a subsequent memory device in the series, for providing a serial enable signal from the controller for enabling or disabling each of the plurality of memory devices.

4. The system of claim 3 wherein for the plurality of memory devices, the enable output of an M-th memory device in the series is terminated or left open.

5. The system of claim 1 wherein each of the plurality of memory devices is configured to store an assigned device identifier.

6. The system of claim 1 wherein:
each of the plurality of memory devices is configured to store an assigned device identifier; and
the controller is configured to assert commands on the common bus comprising a command string having an address field containing a device identifier of an individual memory device to participate in a transaction.

7. The system of claim 1 wherein for addressing an individual memory device, the controller is configured to assert commands on the common bus comprising an identification cycle, each command comprising a command string having an address field comprising a device identifier of the individual memory device.

8. The system of claim 7 wherein:
the controller asserts commands comprising a plurality of cycles; and
the identification cycle comprises a first cycle of the command.

9. The system of claim 7 wherein:
the controller asserts commands comprising a plurality of cycles; and
the identification cycle comprises a second or subsequent cycle of the command.

10. The system of claim 7 wherein each memory device comprises:
a storage element configured to store a device identifier; and
control circuitry configured
to extract a device identifier from an address field of an identification cycle of a command received on the parallel links,
to compare the extracted device identifier with the stored device identifier, and
if there is match, to respond to other cycles of the command, otherwise, to await a new command.

11. The system of claim 10 wherein the control circuitry of the memory device is programmed with executable instructions to
parse the address field of the identification cycle of a command; and
compare the extracted device identifier and the stored device identifier to determine if there is a match between the identifiers.

12. The system of claim 1 wherein each memory device or chip comprises a serial enable input, a serial enable output and a storage element for storing an assigned device identifier.

13. The system of claim 12 wherein the serial enable input is coupled to the serial enable output through a delay element providing a pre-defined delay, to incur an incremental delay of the pre-defined delay as the serial enable signal propagates through each memory device in series.

14. The system of claim 13 wherein, in an initialization cycle, for assigning device identifiers to each of the plurality of memory devices, the controller is configured, on power up, to assert an enable signal via the serial enable link, and as a transition of the enable signal propagates serially through each of the memory devices incurring the pre-defined delay in each memory device, the controller asserts a command cycle on the parallel link, during each corresponding time window corresponding to the pre-defined delay, for storage of a respective device identifier in the device identifier register of the corresponding memory device.

15. The system of claim 1 comprising at least one channel, wherein:
each channel comprises a plurality of memory devices that are interconnected to the controller by a multidrop parallel bus; and
the controller has a single enable output pin per channel for outputting a serial enable signal.

16. The system of claim 1 wherein:
the system comprises a plurality of channels, each channel comprising a plurality of memory devices; and
each channel has a single serial enable link for asserting a single serial enable signal for enabling and disabling all memory devices on the channel, the disabling comprises putting all memory devices on the channel into a low power mode or sleep mode.

17. A system comprising a plurality of memory devices and a controller, wherein:
the plurality of memory devices and the controller are interconnected through a common bus providing parallel links,
each memory device comprises a serial enable input and a serial enable output, and
the controller has a single enable output pin for providing an enable signal to the enable input of a first memory device,
the plurality of memory devices being coupled in series through a serial enable link,
the enable output of each memory device being serially coupled to the enable input of a subsequent memory device in the series.

18. The system of claim 17 wherein:
the controller comprises identification circuitry configured to assign to each memory device a respective unique device identifier; and
each memory device comprises a storage element for storing an assigned device identifier.

19. The system of claim 17 wherein:
each memory device stores an assigned device identifier, and
the controller comprises
identification circuitry configured to assign a unique identifier to each of the plurality of memory devices and
command circuitry configured to insert into commands asserted on the common bus an address field containing the assigned device identifier of a target device to participate in a transaction.

20. The system of claim 19 wherein each memory device comprises identification circuitry configured to
extract a device identifier from a command asserted by the controller,
determine if the extracted device identifier matches the assigned device identifier, and
process the command in response to a match determination.

21. The system of claim 17 wherein, for addressing a command to an individual memory device of the plurality of memory devices,
each memory device comprises a holder configured to store an assigned device identifier;
the controller comprises identification circuitry configured to assign a unique identifier to each memory device and on assertion of a command, for inserting into a command string on the common bus an identification cycle, wherein an address field in the command string contains a device identifier of a targeted individual device; and
each memory device comprises control circuitry configured to
extract a device identifier from the address field of the command string of an identification cycle,
determine if the extracted device identifier matches the assigned device identifier, and
if there is a match, participate in the other cycles of the command, or if there is no match, await another command.

22. A memory device comprising:
a plurality of parallel input/output connections configured to couple to a common bus of a controller;
a serial enable input and a serial enable output; and
a storage element for storing an assigned device identifier.

23. The memory device of claim 22 further comprising control circuitry configured to
extract a device identifier from an address field of command string of an identification cycle on the common bus, and
determine whether the extracted device identifier matches a stored device identifier, and
process the command string in response to a match determination.

24. The memory device of claim 22 wherein the serial enable input is coupled to the serial enable output through a delay element.

25. The memory device of claim 24 wherein the delay element comprises a buffer.

26. A method of operating a system comprising a plurality of (N) memory devices and a controller, the plurality of memory devices being interconnected to the controller by a common bus comprising parallel links, each memory device comprising a serial enable input and serial enable output, each of the plurality of the memory devices being coupled serially through a single serial enable link from an enable output of the controller, the method comprising:
assigning to each memory device a unique device identifier and storing the assigned device identifier in a storage element of the memory device;
on the serial enable link, asserting a single serial enable signal for enabling the plurality of memory devices;
asserting a command on the common bus, wherein for a command targeting an individual memory device, said command comprises an address field containing a device identifier of the individual memory device.

27. The method of claim 26 further comprising asserting a single enable signal to disable the plurality of memory devices.

28. The method of claim 27 wherein asserting a single enable signal to disable the plurality of memory devices comprises putting all memory devices into a low power or sleep mode.

29. The method of claim 26 wherein the asserting a command comprises:
is asserting a command string comprising an identification cycle including the address field containing a device identifier of the individual memory device;
at each memory device, in an identification cycle, extracting the device identifier,
determining if the extracted device identifier matches the assigned device identifier; and
in the memory device matching the extracted device identifier, further processing other cycles of the command string.

30. The method of claim 29 wherein the extracting comprises:
extracting a first cycle or a subsequent cycle of a plurality of cycles of a command string.

31. The method of claim 29 wherein the asserting a command further comprises:
in the memory device not matching the extracted device identifier, ignoring other cycles of the command string and awaiting another command.

32. The method of claim 26 wherein the assigning to each of the plurality of memory devices a unique device identifier comprises:
asserting a enable signal via the serial enable link, and as the transition of the enable signal propagates serially through each of the memory devices incurring a pre-defined delay in each memory device,
asserting a command on the parallel link, during a time window corresponding to the pre-defined delay, for storage of a respective device identifier in the device identifier register of the corresponding memory device.

33. The method of claim 32 wherein for a system comprising the N memory devices, the method comprises:
asserting said command for storage of a respective device identifier, for an i-th memory device, during the time window after a respective delay of (i−1)×(the pre-defined delay) for each of the memory devices.

34. The method of claim 33 wherein the assigning device identifiers is implemented on power up, after assertion of a single enable to enable all memory devices; and on assertion of enable signals to enable, disable or put the memory devices into low power mode, programming of the assigned device identifiers is maintained until power down.

35. The method of claim 26 wherein the step of assigning device identifiers further comprises obtaining a count of the plurality of memory devices.

36. A method of addressing individual memory devices for controlling data transfer in a system comprising a controller and a plurality of memory devices that are interconnected by a parallel link and wherein the plurality of memory devices are connected in series by a serial enable link from the controller, the method comprising:
in an initialization phase, assigning to each of the memory devices a unique device identifier;
and then, in normal operation:
asserting a single enable signal via the serial enable link for enabling each of the plurality of memory devices;
asserting a command on the parallel link, wherein an address field of an identification cycle of the command comprises a device identifier of an individual device of the plurality of memory device;
at each memory device, in an identification cycle, extracting the device identifier, determining if the extracted device identifier matches the assigned device identifier; and
in the memory device matching the extracted device identifier, further processing other cycles of the command.

37. The method of claim 36 wherein memory devices not matching the extracted device identifier ignore other cycles of the command and await another command.

38. The method of claim 36 wherein the assigning to each of the plurality of memory devices a unique device identifier comprises:
asserting a enable signal via the serial enable link, and as the transition of the enable signal propagates serially through each of the memory devices incurring a pre-defined delay in each memory device, asserting a command on the parallel link, during a time window corresponding to the pre-defined delay, for storage of a respective device identifier in the device identifier register of the corresponding memory device.

39. The method of claim 37 wherein for a system comprising the N memory devices, the method comprises:
asserting said command for storage of a respective device identifier, for an i-th memory device, during a time window of a pre-defined delay after a respective delay of (i−1)×(the pre-defined delay) for each of the memory devices.

40. The method of claim 39 wherein the initialization cycle is implemented on power up, after an initial assertion of a single enable to take all memory devices out of low power mode.

41. The method of claim 39 wherein the initialization cycle comprises obtaining a count of the plurality of memory devices.

42. The method of claim 36 further comprising asserting a single enable signal to enable or disable each of the plurality of memory devices.

43. The method of claim 42 wherein after asserting a serial enable signal, waiting sufficient time to allow the serial enable signal to be propagated through the serial enable link interconnecting each of the plurality of memory devices accounting for any delays incurred, before enabling or disabling or otherwise processing a command.

44. A memory system comprising:
a plurality of memory devices, each of the memory devices comprising a storage element configured to store a device identifier;
a parallel interface providing links via a common bus to each memory device; and
a serial enable interface providing a serial enable link connecting each of the memory devices in series, for asserting a single enable signal for enabling or disabling the plurality of memory devices.

45. The memory system of claim 44 wherein each of the plurality of memory devices further comprises control circuitry configured to
extract a device identifier from an address field of an identification cycle of a command received on the parallel interface,
determine whether the extracted device identifier matches the stored device identifier, process other cycles of the command in response to a match result, and await a new command in response to a non-match result.

46. The memory system of claim 45 wherein the control circuitry of the memory device is programmed with executable instructions to:
parse a target address field of the identification cycle of a command,
compare an extracted and stored device identifier, and
determine if there is a match.

47. A memory controller for controlling a channel of a memory system comprising a plurality of memory devices, the controller comprising:
an interface for a common bus configured to provide parallel links to each of the plurality of memory devices, and
a single serial enable output per channel.

48. The memory controller of claim 47 further comprising:
identification circuitry configured to assign a unique identifier to each of the plurality of memory devices; and
command circuitry configured to insert into commands asserted on the common bus an address field containing the assigned device identifier of a target device to participate in a transaction.

49. The memory controller of claim 47 further comprising:
an identification producer configured to produce a unique identifier to be assigned to each of the plurality of memory devices, and
a command provider configured to provide a command to the common bus during a command cycle comprising an identification cycle, the command string of the identification cycle having an address field comprising the device identifier of an individual memory device to participate in a transaction.

50. The memory controller of claim 49 wherein the command cycle comprises a plurality of cycles, the identification cycle comprising a first cycle.

51. The memory controller of claim 49 wherein:
the command cycle comprises a plurality of cycles; and
the identification cycle comprises a second or subsequent cycle.

52. The memory controller of claim 49 wherein for assignment of device identifiers, the command provider is configured to:
assert an enable signal via the serial enable output, and
as the transition of the enable signal propagates serially through each of the memory devices incurring a pre-defined delay in each memory device, assert a command cycle on the parallel link during a time window corresponding to the pre-defined delay, for storage of a respective device identifier in a device identifier register of a corresponding memory device.
